(19) United States
(12) Patent Application Publication
(10) Pub. No.: US 2001/0008804 A1
(43) Pub. Date: Jul. 19, 2001

(54) Device for dry etching a wafer and appertaining method

(76) Inventor: Franz Sumnitsch, Osterreich (DE)

Correspondence Address: HARDING, EARLEY, FOLLMER & FRAILEY, 86 THE COMMONS AT VALLEY FOR. E., 1288 VALLEY FORGE RD., P.O. BOX 750, VALLEY FORGE, PA, 19482, US

(21) Appl. No.: 09/800,172

(22) Filed: Mar. 6, 2001

Related U.S. Application Data
(62) Division of application No. 09/251,086, filed on Feb. 16, 1999.

(30) Foreign Application Priority Data
Feb. 18, 1998 (DE) 198 06 815.8
Jun. 25, 1998 (DE) 198 28 290.7

(51) Int. Cl. H01L 21/302

(52) U.S. Cl. 438/706

(57) ABSTRACT

The invention refers to a device and a method for dry etching a defined near-edge portion of a surface of a coated wafer (semiconductor disk).

The invention refers to a device and a method for dry etching a defined near-edge portion of a surface of a coated wafer (semiconductor disk).

Such a wafer, for example based on silicon, may have a coating based on silica on all sides, for example. For subsequent processes, (for example, if a layer of gold or a layer of polysilicon (polycrytalline silicon) is to be deposited) it may be necessary to remove the existing coating from the wafer at least in the edge region of a main surface but also in the region of its peripheral surface and/or the second main surface, if necessary. This is effected by etching processes which can be divided into dry etching processes and wet etching processes, above all.

The invention is directed towards the dry etching of wafers. Here, the coating to be removed (a layer of silica, for example) is treated with a gaseous etchant (for instance hydrogen fluoride), gaseous silicon tetrafluoride (SiF₄) forming in the process.

The EP 0 701 276 A2 describes a method for etching a wafer on one side with HF gas. The etching of the other side of the wafer is prevented in that this side is washed with an inert gas during the etching process.

From the U.S. Pat. No. 5,384,008 a method and a device for depositing a material layer onto a surface of a wafer are known, that is without remnants on the back of the wafer. To remove such remnants on the back of the wafer the wafer is placed upon a support in such a manner that the edge region of the support projects. To this end the support surface has a corresponding recess in the edge region of the wafer, for example. In this way the free projecting lower edge region of the wafer may be etched in a subsequent etching process.

However, no defined edge region can be etched off in that way; rather a relatively irregular boundary contour develops on the lower surface of the wafer in the boundary region between the support and the wafer.

The object of the invention is to show a possibility to remove the coating from a defined portion at the edge on at least one surface of a wafer by dry etching, that is for example to etch off a ring portion at the edge with defined width on at least one surface in a round semiconductor disk.

Coming from this object it would have been obvious, for example, to cover the wafer surface except the portion to be etched or to protect it from the etching agent with a veil of inert gas as indicated by the EP 0 701 276 A1. In fact, coating portions at the edge of a wafer surface may be etched off in this manner but with an “irregular” contour. In particular in the region of transition between the etched and the non-etched surface no defined boundary zone can be formed in this manner, obviously because of the uncontrollable processes of diffusion of the etching gas in that region.

It has been found by systematical experiments that such diffusion processes may be used, however, to form a defined boundary line between the surface to be etched (etched surface) and the surface not to be etched of the wafer.

Though, such a defined boundary line can be obtained only if the said diffusion processes can be effective over a “certain distance”.

For that the invention provides a device for dry etching a defined near-edge portion of at least one surface of a coated wafer, having the following features:

an etching chamber having

at least an inlet port for a gaseous etching agent,

a support disposed within the interior space of the etching chamber and having a bearing surface for the wafer, as well as

at least a discharge port for excess etching agent and possible reaction products produced by the etching process,

the support being formed to project with its outer contour all round beyond the inner contour of the surface portions to be etched.

The etching chamber serves for receiving the wafer to be treated and for creating a defined space of treatment. The etching agent, for example HF gas, is supplied to the interior space of the etching chamber via an inlet port.

Within the interior space of the etching chamber, the support serves for receiving the wafer to be treated. It is useful to arrange the bearing surface for the wafer horizontally to facilitate the wafer to be supported securely and a uniform etching treatment at the periphery. In this sense, it is also useful to arrange the support and thus the wafer in the middle of the etching chamber and to design the etching chamber in rotationally symmetrical manner for a round wafer, for example

Since the supply of the etching agent is usually effected continuously, at least a discharge port is provided through which excess or used etching gas may be removed as well as possible reaction products produced by the etching process.

The crucial feature of the device is the concrete geometric design of the support. Its outer contour, that is the peripheral line of its bearing surface, has to be larger than the inner contour, that is the inner peripheral line of the surface portion to be etched off. Of course there is the other requirement that the peripheral line of the wafer surface portion to be etched off is within the outer contour of the support, when the wafer is placed upon it.

Usually the wafer will have the form of a circular disk. From a supposed outer diameter D of the wafer and the requirement to etch off a ring-shaped portion having an inner diameter d (with D>d) on one surface of the wafer in its edge region results for the geometry of the support that the supposed ring-shaped or annular support has an outer diameter d+x with x>0.

Starting from an example of application in which (d+x)< D, it has been found that in the beginning the etching agent mainly etches off the surface portion of the wafer at the edge, which projects beyond the support; but then the etching agent penetrates into the region between the bearing surface of the support and the corresponding surface portion of the wafer and etches off via diffusion processes the wafer coating in this portion as well, in correspondence with an increasing depth of penetration of the etchant. Surprisingly, the etching agent penetrates into the region of contact between the support and the wafer with a uniform depth on all sides so that as a result an exactly definable boundary line is formed between the etched and the non-etched surface portion of the wafer in the wafer/support contact region.

Usually the outer contour of the support will have the same distance all round from the inner contour of the surface portion to be etched off the wafer. In particular, this is true for circular semiconductor disks in which a defined ring surface is to be etched off at the edge.

But it is easily possible to form individual boundary lines, for example having a wave-like shape or rectilinear portions.

According to an embodiment, the bearing surface of the support for the wafer is considerably smaller than the wafer surface.

So, the support may have a ring shape, for example, the width of the ring (or generalized: the width of the bearing surface) being selected in accordance with the teaching above so that it also covers at least part of the surface portion not to be etched off.

Resting of the wafer on a relatively narrow bearing surface stabilizes the position of the wafer on the support.

According to an embodiment, the distance between the inner contour of the surface portion to be etched of the wafer and the outer contour of the support is 1 to 6 mm.

According to another embodiment it is provided that the outer contour of the bearing surface of the support is equal to or even larger than the outer contour of the wafer.

Here, the etching at the edge is effected only via the diffusion processes mentioned above but defined in the same way so that as a result a defined boundary line, for example a perfect circular line, is formed as well between the etched and the non-etched surface portion of the wafer.

Resting of the wafer on the support as well as the said diffusion processes may be optimized in that the bearing surface of the support, opposite of the surface portion to be etched off the wafer, has at least a groove all round. The depth and the width of the groove may be limited to dimensions of a few μm.

Auxiliary tools are required to put the wafer onto or to remove it from the support. Mounting/dismounting may be made easier by a lifting device acting on the wafer.

This lifting device may for example consist of vertically displaceable pins, preferably at least three pins, which lift the wafer up and thus disengage it from the support for removal.

In order to be able to etch off an edge portion having a constant width in rotationally symmetrical wafers, positioning means for a concentric arrangement of the wafer with respect to the support can be provided as well. For example, those may consist of guiding elements (for example guiding pins) which are arranged along the outer contour (the outer diameter) of the wafer to be treated. In the case of for instance three pin-like guiding elements the wafer correspondingly lies against the guiding pins in three points of its periphery, which in this case preferably have an angle of 120°from each other.

The corresponding guiding elements may also be used for mounting or dismounting the wafer.

The device may also be used to etch off both surfaces of a wafer at the edge In this case the wafer is covered on the upper surface by a corresponding “mask”, the same conditions as for the support being valid for the geometry of the mask. Here also the mask may have a hat-like shape, for example, that is rests on the wafer surface only at the edge.

Finally, it is also possible to treat the wafer in such a manner that its lower surface at the edge as well as the peripheral surface and its upper surface are etched. In this case, only the arrangement of the support mentioned at the beginning is required.

The appertaining method for dry etching of at least a defined near-edge portion of at least one surface of a coated wafer by a gaseous etching agent is characterized in that the wafer is placed upon the bearing surface of a support in such a manner that the support with the outer contour of its bearing surface projects all round beyond the inner contour of the near-edge surface portion to be etched and in that the etching process is performed until the etching agent has etched off the coating of the wafer in its near-edge surface portion covered by the bearing surface of the support in the desired defined amount.

In that, during the etching process, unused etching agent and reaction products produced by the etching process, for example SiF₄, H₂, may be withdrawn and new etching agent may be supplied at the same time and these two procedure steps may be repeated as often until the etching agent has etched off the coating of the wafer in its near-edge surface portion covered by the bearing surface of the support, in the desired defined amount.

According to another modification of the method the near-edge portion of the wafer, extending inwardly from its peripheral edge, is placed upon an area of the bearing surface of the support, which is at least as wide as the near-edge surface portion of the wafer to be etched off. It is ensured in this way that the boundary line between the etched-off surface portion of the wafer and the surface portion which is not etched off is in the region of contact between the support and the wafer, as described in detail above.

It has been mentioned already that also the surface of the wafer opposite the support may be treated in an analogous manner. For that an embodiment provides to cover this surface of the wafer by a cover which leaves a near-edge surface portion of the wafer extending all round free, but projects with its outer contour beyond the inner contour of the near-edge surface portion to be etched on this surface of the wafer. In principle, the features already described above for the “under etching” are applied analogously to the upper surface of the wafer.

Normally, unused etching agent as well as produced reaction products should be withdrawn before a reaction product (for example wafer) produced by the etching process condenses on the wafer.

The method may be performed at room temperature and atmospheric pressure.

Otherwise, the same features and advantages follow with respect to the method as described with the device.

Accordingly, the method can be performed with the described device. As explained in more detail below with the description of the figures, the support (the bearing for the wafer) may have a recess within that region in which the wafer lies upon the support. By this recess a potential problem in a wafer being supported all-over is avoided. In a wafer being supported all-over on a supporting surface it may not be disposed everywhere in its edge region with the same distance from the bearing surface, which also may result in a nonuniform or irregular undercut. If the wafer is supported only in its edge region to be etched, there also results the advantage that the region of the wafer (the semiconductor disk), in which chips are to be produced later on, is not touched.

Further features of the invention follow from the features of the subclaims as well as the other application documents.

The invention is explained in more detail below with an embodiment.

Here, the figures show in diagrammatic view, respectively;

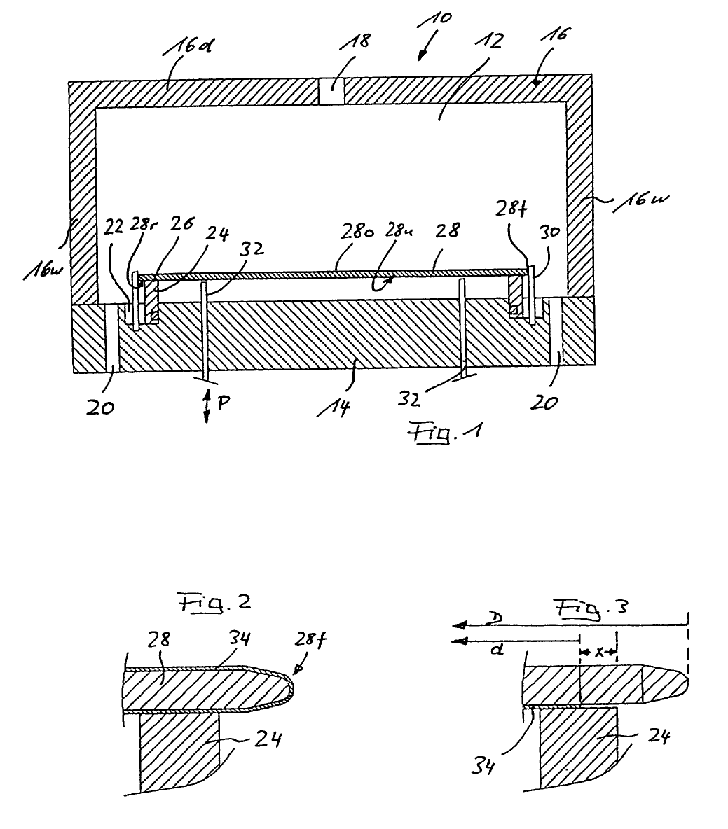

FIG. 1 a vertical section through a device according to the invention,

FIG. 2 an enlarged illustration of a section of a support with a wafer being supported on it before the etching treatment,

FIG. 3 an enlarged illustration of a section of a support with a wafer being supported on it after the etching treatment.

FIG. 1 shows an etching chamber 10 having a circular interior space 12 delimited at the lower side by a bottom 14 and at the upper side by a bell-shaped hood 16. The hood 16 is removably placed upon the bottom 14.

An inlet port 18 is provided in the cover 16d of the hood 16, joined by a pipe (not illustrated), which leads an etching gas, here HF gas, into the interior space 12 of the etching chamber 10.

Several openings 20 are provided in the bottom 14, that is each adjacent to the wall portion 16w of the hood 16, which serve for withdrawal (discharge) to the used and excess etching gas, respectively.

A ring-like recess 22 extends in the bottom 14 on the inside beside the openings 20.

An annular support 24 is inserted on the inner wall of the recess 22, which projects upwardly beyond the recess 22 and the surface-ground upper end face 26 of which forms a horizontal bearing surface for a wafer 28 which here has the form of a circular disk with the outer diameter D: In accordance with the shape of the support 24 the middle portion of the wafer 28 is not supported by the support 24.

As can be seen from the figure, the wafer 28 is arranged in concentric relationship to the support 24 and projects at the periphery beyond the support 24 with equal distance.

Several pins 30 lie against the outer periphery of the wafer 28 which are fixed in the bottom 14 in the region of the recess 22.

Furthermore, lifting rods 32 are disposed in the bottom 14, again at the inside of the support 24, which are vertically adjustable in the direction of arrow P and serve for example for lifting the wafer 28 from the support 24 in an upward vertical displacement, so that the wafer 28 may be removed afterwards (after previous removal of the hood 16) and replaced by a new wafer 28.

The function of the device is the following:

After inserting a wafer 28 onto the support 24 and placing the hood 16 upon the bottom 14 the etching gas is supplied to the interior space 12 of the etching chamber 10 via the inlet port 18.

The etching gas washes around the upper surface 28o of the wafer 28, the peripheral surface 28f of the wafer 28 and first the portion 28r of the lower surface 28u of the wafer 28, which laterally projects beyond the support 24.

Correspondingly, first the surface coating of the wafer 28 is etched off in these areas. However, then the etching gas penetrates by diffusion processes from the outside into the region of contact between the support 24 (respectively its end face 26) and the corresponding surface portion on the lower surface 28u of the wafer 28 so that the etched-off edge region of the lower surface 28u of the wafer 28 extends radially towards the inside, as illustrated in FIG. 3, that is over a distance x (FIG. 3). This etching process is also called “undercut” (under etching) because the “lower surface” of the wafer is etched.

In comparison with FIG. 2 showing the wafer 28 on the support 24 before the etching treatment, it can be seen that now the surface coating 34 of the wafer 28 is etched off totally on the upper surface 28o, totally as well on the peripheral surface 28f and over a distance (D-d)/2 on the lower surface 29u, d describing the outer diameter of the coating 34 of the lower surface 28u of the wafer 28, which is not etched off, and the inner diameter of the etched-off region of the lower surface 28u of the wafer 28, respectively.

The exceptional feature in the method described above is that the etching is effected also in the region of contact between the support 24 and the wafer 28 and a defined boundary line, here a perfect circular line having the diameter d, is formed at the same time.

1. A device for dry etching a defined near-edge portion of at least one surface (28u) of a coated wafer (28) having the following features:
1.1 an etching chamber (10) having
1.1.1 at least an inlet port (18) for a gaseous etching agent,
1.1.2 a support (24) disposed within the interior, space (12) of the etching chamber (10) and having a bearing surface (26) for the wafer (28), as well
1.1.3 at least a discharge pots (20) for excess etching agent and possible reaction products produced by the etching process,
1.2 the support (24) being formed to project with its outer contour all round beyond the inner contour of the surface portion to be etched.

2. The device according to claim 1, wherein the outer contour of the support (24) has the same distance all round from the inner contour of the surface portion to be etched of the wafer (28).

3. The device according to claim 1, wherein the distance of the inner contour of the surface portion to be etched of the wafer (28) from the outer contour of the support (24) is 1 to 6 mm.

4. The device according to claim 1, wherein the outer contour of the support (24) corresponds to the outer contour of the wafer (28), at most.

5. The device according to claim 1, wherein the support (24) has a ring shape.

6. The device according to claim 1, wherein the outer diameter of the support (24) is larger than the inner diameter of the surface portion to be etched of the wafer (28).

7. The device according to claim 1, wherein the hearing surface (26) of the support (24), composite the surface portion to be etched of the wafer, has at least a groove all round.

8. The device according to claim 1 having a lifting device (32) acting on the wafer (28).

9. The device according to claim 8, wherein the lifting device (32) consists of vertically displaceable pins.

10. The device according to claim 1 having guiding elements (30) for the wafer (28), being disposed along the outer contour of the wafer (28) to be treated.

11. A method for dry etching a defined near-edge portion of at least one surface of a coated wafer by a gaseous etching agent, wherein the wafer is placed upon the bearing surface of a support in such a manner that the support with the outer contour of its bearing surface projects all round beyond the inner contour of the near-edged surface portion to be etched and the etching process in performed until the etching agent has etched off the coating of the wafer in its near-edge surface portion covered by the bearing surface of the support in the desired defined amount.

12. The method according to claim 11, wherein unused etching agent and reaction products produced by the etching process are withdrawn, new etching agent is supplied and these two procedure steps are repeated during the etching process until the etching agent has etched off the coating of the wafer in its near-edge surface portion covered by the bearing surface of the support in the desired defined amount.

13. The method according to claim 11, wherein the near-edge portion of the wafer extending inwardly front its peripheral edge is placed upon an area of the bearing surface of the support which is at least as wide as the near-edge surface port on of the wafer to be etched off.

14. The method according to claim 11, wherein a cover is placed upon the surface of the wafer opposite the support, which leaves a near-edge surface portion of the wafer extending all round free, which extends all round, but projects with its outer contour beyond the inner contour of the near-edge surface portion to be etched on this surface of the wafer.

15. The method according to claim 12, wherein the unused etching agent and the produced reaction products are withdrawn before a reaction product produced by the etching process condenses on the wafer.

16. The method according to claim 11, wherein the etching process is performed at room temperature and atmospheric, pressure.
